(19) United States
(12) Patent Application Publication
(10) Pub. No.: US 2010/0238963 A1
(43) Pub. Date: Sep. 23, 2010

(54) Gallium nitride based semiconductor laser device

(75) Inventor: Akira Tanaka, Kanagawa-ken (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: Kabushiki Kaisha Toshiba, Minato-ku (JP)

(21) Appl. No.: 11/476,931

(22) Filed: Jun. 29, 2006

(30) Foreign Application Priority Data
Jun. 29, 2005 (JP) 2005-189174

(51) Int. Cl. H01S 5/343; H01S 5/34

(52) U.S. Cl. 372/45.012; 372/45.01

(57) ABSTRACT

A gallium nitride based semiconductor laser device comprises: a first cladding layer having a first conductivity type; an active layer provided on the first cladding layer; an overflow prevention layer having a second conductivity type provided on the active layer; and a second cladding layer having the second conductivity type provided on the overflow prevention layer. The second cladding layer has a ridge portion and a non-ridge portion, and is made of an AlₓGa₁₋ₓN (0.015≦x≦0.040). Alternatively, the second cladding layer has a superlattice layer of Al_{y}Ga_{1-y}N (0.015≦y≦1) layers and GaN layers with an average aluminum composition ratio of 0.015 or more and 0.040 or less. A thickness of the ridge portion is not less than a thickness of the non-ridge portion and not more than 0.45 micrometers.

### CROSS-REFERENCE TO RELATED APPLICATION

This application is based upon and claims the benefit of priority from the prior Japanese Patent Application No. 2005-189174, filed on Jun. 29, 2005; the entire contents of which are Incorporated herein by reference.

### BACKGROUND OF THE INVENTION

The development of the next-generation DVD (Digital Versatile Disc) has been in progress for the long-term recording of high-definition videos and for computer mass storage. In order to achieve a recording capacity four times or more than that of conventional DVDs, the wavelength of the semiconductor laser device must be in the 400-nm band rather than in the conventional 650-nm band. To this end, gallium nitride based materials are used.

For the purpose of rewriting and reading a high-density optical disc, a gallium nitride based ridge waveguide semiconductor laser device is used, which has the following configuration: A double heterojunction using InGaAlN-based materials is grown on a gallium nitride substrate, and the upper p-type cladding layer is configured as a ridge shape. However, gallium nitride based materials are susceptible to lattice mismatches and crystal defects as compared to InGaAlP-based materials, and thereby results in deteriorating the characteristics and reliability of semiconductor laser devices.

There are disclosures of an InGaAlN-based semiconductor laser device in which the composition ratio of constituent elements is optimized to reduce lattice mismatches and crystal defects and the ridge structure is optimized to improve optical confinement (e.g., JP 2002-094190A). However, according to the teachings of these disclosures, it is difficult to achieve the characteristics required for rewritable applications, such as an optical power of 100 mW or more, an optical beam quality having a FFP (Far Field Pattern) suitable for rewriting, and a long-term reliability.

### SUMMARY OF THE INVENTION

According to an aspect of the invention, there is provided a gallium nitride based semiconductor laser device comprising: a first cladding layer having a first conductivity type; an active layer provided on the first cladding layer; an overflow prevention layer having a second conductivity type provided on the active layer; and a second cladding layer having the second conductivity type provided on the overflow prevention layer, the second cladding layer having a ridge portion and a non-ridge portion, and made of an Alₓ (0.015≦x≦50.040), and a thickness of the ridge portion being not less than a thickness of the non-ridge portion and not more than 0.45 μm.

According to other aspect of the invention, there is provided a gallium nitride based semiconductor laser device comprising: a first cladding layer having a first conductivity type; an active layer provided on the first cladding layer; an overflow prevention layer having a second conductivity type provided on the active layer; and a second cladding layer having the second conductivity type provided on the overflow prevention layer, the second cladding layer having a ridge portion and a non-ridge portion, and a superlattice layer of Al_{y}Ga_{1-y}N (0.015≦y≦1) layers and GaN layers with an average aluminum composition ratio of 0.015 or more and 0.040 or less, and the thickness of the ridge portion being not less than the thickness of the non-ridge portion and not more than 0.45 p.m.

### BRIEF DESCRIPTION OF THE DRAWINGS

FIG. 1 is a schematic cross section of a gallium nitride based semiconductor laser device according to an example of the invention;

FIG. 2 is a band diagram of the gallium nitride based semiconductor laser device according to the example of the Invention;

FIG. 3 is a graphical diagram showing the ridge thickness dependence of the operating current for the gallium nitride based semiconductor laser device according to the example of the invention;

FIG. 4 is a schematic cross section of a gallium nitride based semiconductor laser device of a comparative example;

FIG. 5 is a graphical diagram showing the cladding layer aluminum composition ratio dependence of the operating current for the gallium nitride based semiconductor laser device of the comparative example;

FIG. 6 is a graphical diagram showing the measurements of the CW optical power versus operating current characteristics for the present example and the comparative example;

FIGS. 7 to 9 are process cross sections illustrating the relevant part of a process of manufacturing a gallium nitride based semiconductor laser device having a thick insulating film; and

FIG. 10 shows a variation of the present example.

### DETAILED DESCRIPTION OF THE INVENTION

Embodiments of the invention will now be described with reference to the drawings.

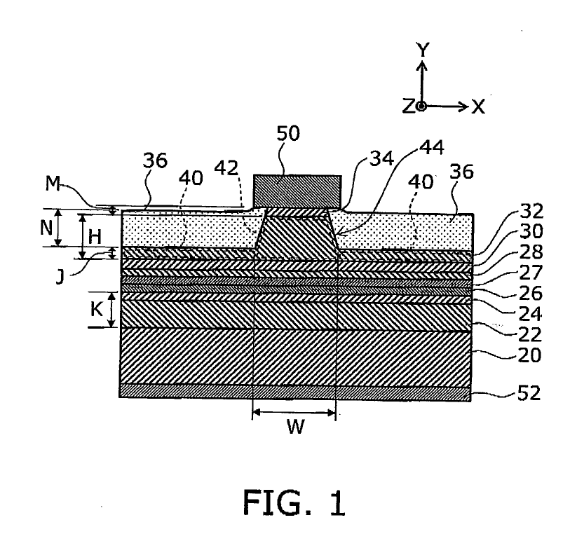

FIG. 1 is a schematic cross section of a gallium nitride based semiconductor laser device according to an example of the invention. On an n-type GaN substrate 20, an n-type Al_{0.04}Ga_{0.96}N cladding layer 22 (with a thickness of 1.5 to 2.0 μm), an n-type GaN optical guide layer 24 (with a thickness of 0.01 to 0.10 μm), and an active layer 26 are laminated.

On the MQW active layer 26, a non-doped GaN diffusion prevention layer 27 (with a thickness of 0.02 to 0.1 μm), a p⁺-type Al_{0.16}Ga_{0.84}N overflow prevention layer 28 (with a thickness of 5 to 20 nm), a p-type GaN optical guide layer 30 (with a thickness of 0.01 to 0.10 μm), a p-type AlₓGa₁₋ₓN cladding layer 32, and a p⁺-type GaN contact layer 34 (with a thickness of 0.02 to 0.10 μm) are laminated. The aluminum (Al) composition ratio x is preferably within the range of 0.015 to 0.040, and more preferably 0.015≦x≦0.035. These semiconductor laminated films can be sequentially grown on the n-type GaN substrate 20 by the MOCVD (Metal Organic Chemical Vapor Deposition) method, for example. Typically, silicon is used as n-type impurities, and magnesium is used as p-type impurities.

The “gallium nitride based semiconductor” used herein includes semiconductors having any composition represented by the chemical formula InₓAl_{y}Ga_{1-x-y}N (0≦x≦1, 0≦y≦1, x+y≦1) where the composition ratios x and y are varied in the respective ranges. Furthermore, the “gallium nitride based semiconductor” also includes those further containing any of various dopants added for controlling conductivity types.

The structure illustrated in FIG. 1 belongs to the refractive index waveguide structure also referred to as the ridge waveguide structure. More specifically, the p-type AlGaN cladding layer 32 comprises a ridge portion 42 with thickness H, represented by dashed line, and a non-ridge portion 40 with thickness J, represented by dashed line. The p⁺-type GaN contact layer 34 on the ridge portion 42 is also patterned at the same time. An insulating film 36 is formed on a side face of the p⁺-type GaN contact layer 34 and a ridge side face 44 of the ridge portion 42, which have been patterned. The insulating film 36 may be made of such materials as silicon oxide film (SiO₂) or silicon nitride film (Si₃N₄). The silicon oxide film has a refractive index of about 1.5, and the silicon nitride film has a refractive index of 1.9 to 2.1.

The p⁺-type GaN contact layer 34 is connected to a p-side electrode 50 made of monolayer, lamination, or alloy of Pt, Pd, Ni, and Au, for example. The n-type GaN substrate 20 is connected to an n-side electrode 52 made of monolayer, lamination, or alloy of Ti, Pt, Au, and Al, for example.

Since the insulating film 36 is provided on the ridge side face 44 of the ridge portion 42, there is a difference of refractive index between the p-type AlGaN cladding layer 32 constituting the ridge portion 42 and the insulating film 36. The p-type AlGaN cladding layer 32 has a refractive index of about 2.526 for Al_{0.035}Ga_{0.965}N and about 2.523 for Al_{0.04}Ga_{0.96}N. Thus, since the ridge portion 42 has a higher refractive index than the insulating film 36, the fundamental horizontal transverse mode is confined horizontally (X axis) relative to the MQW active layer 26 in the cross section orthogonal to the optical axis (parallel to the Z axis). However, if the ridge portion 42 has an excessively large width W at its bottom, higher order horizontal transverse modes will occur. In this example, the width W of the ridge portion 42 is set to 1 to 3 μm, and thereby higher order modes are successfully suppressed.

When the thickness J of the non-ridge portion 40 is close to the thickness H of the ridge portion 42, the region of the ridge portion 42 which protrudes from the non-ridge portion 40 is thinned, which results in weakening the lateral optical confinement and decreasing the efficiency. Therefore, it is preferable that (H-J)≧0.05 μm. Moreover, as described later in detail, the thickness H of the ridge portion 42 is preferably set to 0.45 μm or less.

Next, the function of the laminated structure will be described in more detail.

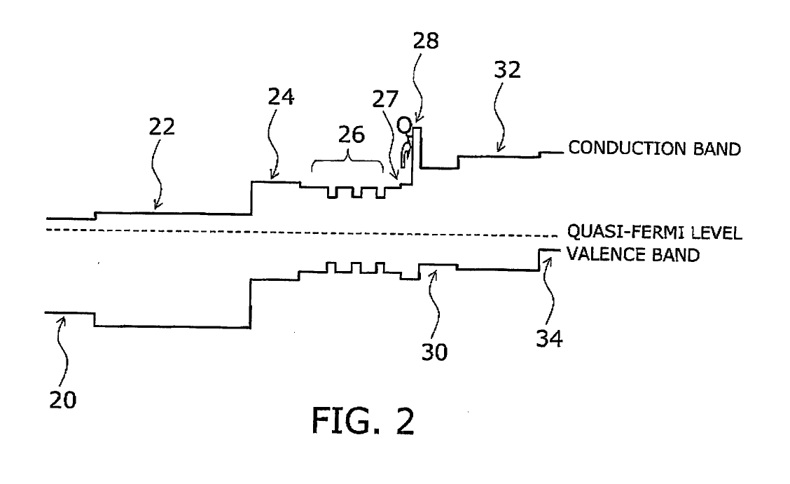

FIG. 2 is a band diagram of a semiconductor laminated structure of this example. The non-doped GaN diffusion prevention layer 27 prevents p-type impurities such as magnesium (Mg) from diffusing from the highly doped p⁺-type AlGaN overflow prevention layer 28 into the MQW active layer 26.

The p⁺-type overflow prevention layer 28 suppresses unnecessary increase of the operating current caused by the fact that electrons Q, as indicated by the arrow, injected from the n-type GaN substrate 20 side are leaked into the p-type AlₓGa₁₋ₓN cladding layer 32.

More specifically, a higher aluminum composition ratio x of the p⁺-type AlₓGa₁₋ₓN overflow prevention layer 28 increases its band gap difference relative to the MQW active layer 26, which can prevent electrons Q injected from the n-side from leaking from the MQW active layer 26 into the p-type AlₓGa₁₋ₓN cladding layer 32. Moreover, since the heterobarrier on the conduction band side relative to the active layer 26 can be increased by increasing the p-type concentration (e.g., up to 1×10²⁰ cm⁻³) of the p⁺-type AlGaN overflow prevention layer 28, the leakage of electrons Q can be further reduced.

Furthermore, a larger aluminum composition ratio typically results in a smaller lattice constant, which may lead to the degradation of crystallinity such as the occurrence of lattice mismatches. However, the influence of the degradation of crystallinity on the p⁺-type AlGaN overflow prevention layer 28 can be reduced because its thickness is as small as 5 to 20 nm, for example. On the other hand, the aluminum composition ratio of the p-type AlGaN cladding layer 32 has an upper bound for preventing the degradation of crystallinity because it is thicker than the p⁺-type AlGaN overflow prevention layer 28.

Next, the beam characteristic for a large aluminum composition ratio is described. With the increase of the aluminum composition ratio, the refractive index decreases, thus strengthening the vertical (Y axis) optical confinement. Therefore, when the aluminum concentration of the p-type AlGaN cladding layer 32 is too large, the vertical beam spread angle (θv) is increased, and its ratio to the horizontal beam spread angle (θh), that is, the aspect ratio (θv/θh), is increased. For effective use of optical power, the aspect ratio is preferably close to unity. An excessively large aspect ratio is practically undesirable because it requires beam shaping lens or the like, which complicates the optical system. In this example, the aspect ratio has an appropriate value when the aluminum composition ratio of the p-type AlGaN cladding layer 32 is in the range of 0.015 to 0.040, or more preferably in the range of 0.015 to 0.035. That is, an aluminum composition ratio of 0.04 or less results in θv of 22° or less, which may eliminate the need for beam shaping lens and the like.

Next, an additional description is given of the components of the laminated structure. The p-type cladding layer 32 is not limited to the p-type AlₓGa₁₋ₓN (0.015≦x≦0.040) bulk layer, but may be a superlattice layer in which the pair of Al_{y}Ga_{1-y}N (0≦y≦1)/GaN is laminated, for example. In both cases of bulk and superlattice, the average aluminum composition ratio is preferably 0.015 or more and 0.040 or less, and more preferably 0.015 or more and 0.035 or less. The superlattice layer can relieve stress due to lattice mismatch and the like (that is, it is effective in preventing cracks) and can reduce the operating voltage. For example, 200 sets of GaN with a width of 2.5 nm and Al_{0.07}Ga_{0.93}N with a width of 2.5 nm can be alternately laminated to achieve a cladding layer having a thickness of 1 μm and an average aluminum composition ratio of 0.035. Additional modulation doping in the GaN layer with magnesium may be more advantageous.

Likewise, the n-type cladding layer 22 is not limited to the n-type Al_{0.04}Ga_{0.96}N layer, but may be AlₓGa₁₋ₓN (0.04≦x≦0.10). It may be a superiattice layer in which the pair of Al_{y}Ga_{1-y}N/GaN is laminated. In this case, the average aluminum composition ratio is preferably 0.04 or more and 0.10 or less. The advantage of the superlattice is similar to that for the p-type cladding layer. The aluminum composition ratio being 0.04 or more in the n-type cladding layer 22 is desirable for reducing the operating current, and being 0.10 or less is desirable for achieving a vertical beam spread angle (θv) of 22° or less.

Moreover, the active layer 26 of InₓGa₁₋ₓN/In_{y}Ga_{1-y}N may be a single or multiple quantum well active layer. In this case, the indium composition ratio x of the well layer can be selected within the range of 0.05 to 0.2, and the indium composition ratio y of the barrier layer can be selected within the range of 0 to 0.05. For example, the structure of In_{0.13}Ga_{0.87}N/In_{0.01}Ga_{0.99}N can be used, where the well layer thickness is 2 to 5 nm, the number of wells is 2 to 4, and the barrier layer thickness is 3 to 10 nm. The composition and profile of the active layer can be varied to adjust the threshold current, FFP, temperature characteristics, and the like.

Furthermore, the overflow prevention layer 28 can be AlₓGa₁₋ₓN with an aluminum composition ratio of 0.15 or more.

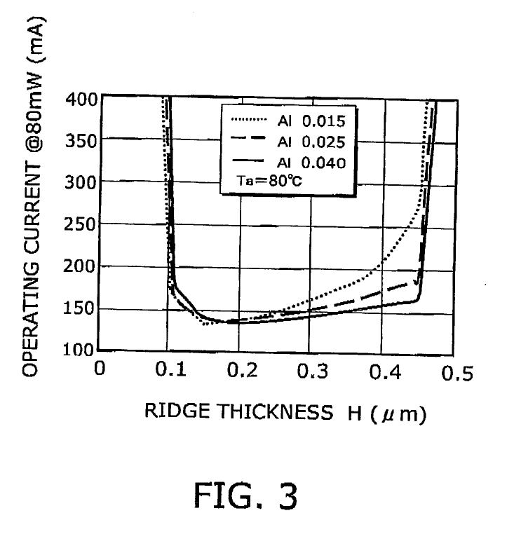

FIG. 3 is a graphical diagram showing the dependence of the operating current at high output power on the thickness H of the ridge portion 42 in the gallium nitride based semiconductor laser device having the ridge portion 42. This result is obtained by simulation using the aluminum composition ratio x as a parameter.

In this example simulation, the thickness J of the non-ridge portion 40 is fixed to 0.05 μm, and the thickness H of the ridge portion 42 of the p-type AlₓGa₁₋ₓN cladding layer 32 is varied within the range of 0.05 to 0.50 μm. The aluminum composition ratio x is selected to be 0.015, 0.025, and 0.04. On the other hand, for the n-type Al_{0.04}Ga_{0.96}N cladding layer 22, the aluminum composition ratio is fixed to 0.04, and the layer thickness is fixed to 1.65 μm. The bottom width W of the ridge portion 42 is set to 1.7 μm.

The front and rear cleaved surfaces constituting the optical resonator of the gallium nitride based semiconductor laser device are provided with reflecting films having a reflectance of 10% and 95%, respectively. Thus the optical output from the front side is enhanced.

In FIG. 3, the vertical axis represents the operating current for a CW optical power of 80 mW at ambient temperature Ta=80° C., and the horizontal axis represents the ridge thickness H (μm). For the thickness H of the ridge portion within the range of 0.15 to 0.45 μm, the operating current as low as 270 milliamperes or less is achieved although it is slightly increasing. For the aluminum composition ratio within the range of 0.015 to 0.040, a practical operating current is achieved although the current tends to be saturated for higher aluminum composition ratios. Decreasing the thickness H of the ridge portion will have no effect for an aluminum composition ratio of 0.05 or more because of strong optical confinement due to this composition ratio, but it is presumably effective for an aluminum composition ratio of 0.04 or less.

However, when the thickness H of the ridge portion 42 is 0.45 μm or more, the operating current rapidly increases. Presumably, one reason for this is that the optical confinement to the MQW active layer 26 is weakened in the vertical transverse (Y axis) direction. Another reason is that the distance from the MQW active layer 26 to the heat dissipation surface increases, which deteriorates the heat dissipation. That is, in high power applications, the p-side electrode 50 is often bonded to a metal heat sink for heat dissipation with eutectic solder or the like.

The thickness H of the ridge portion 42 should be not less than the thickness 3 of the non-ridge portion 40 (being set to 0.05 μm here). Otherwise, the confinement of horizontal transverse modes (X axis) is made incomplete, and thereby the efficiency is decreased.

Next, a comparative example is described.

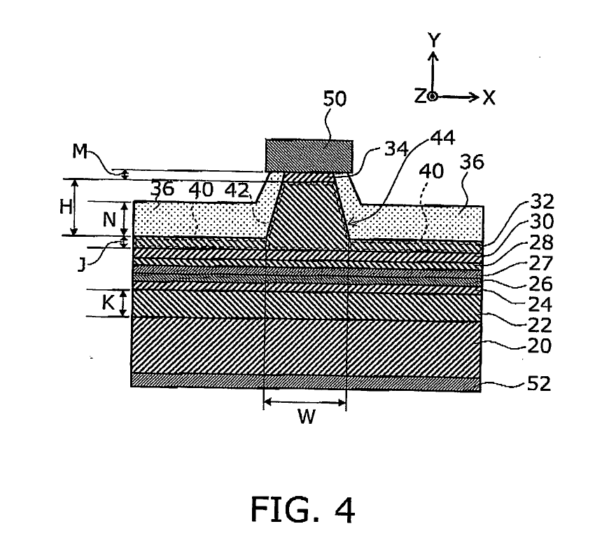

FIG. 4 is a schematic cross section of a gallium nitride based semiconductor laser device of a comparative example. Elements similar to those in FIG. 1 are marked with the same reference numerals and not described in detail. For the n-type Al_{y}Ga_{1-y}N cladding layer 22 and the p-type AlₓGa₁₋ₓN cladding layer 32, the aluminum composition ratios x and y are varied within the range of 0.02 to 0.05 where x=y. The thickness H of the ridge portion 42 of the p-type AlₓGa₁₋ₓN cladding 32 is set to 0.5 μm.

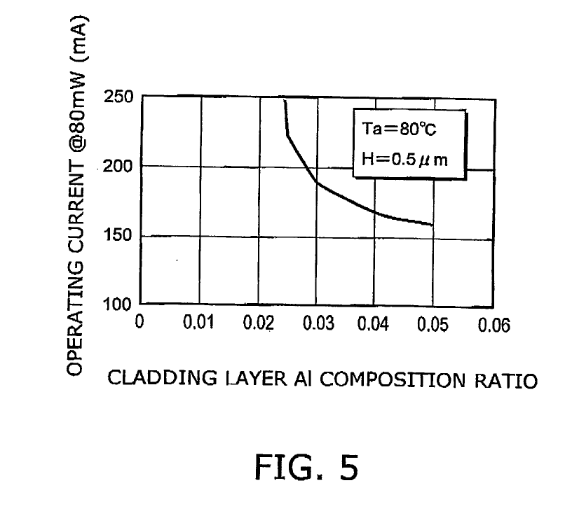

FIG. 5 is a graphical diagram showing the simulation result for this comparative example. The vertical axis represents the operating current at an optical power of 80 mW, and the horizontal axis represents the aluminum composition ratio x of the p-type AlₓGa₁₋ₓN cladding layer 32.

In this comparative example, the operating current rapidly increases when the aluminum composition ratios x and y (where x=y) of the cladding layer are 0.03 or less.

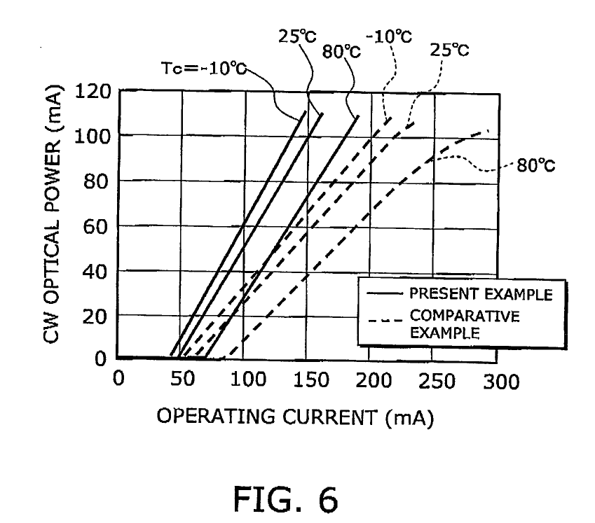

FIG. 6 is a graphical diagram showing the measurements of the CW optical power versus operating current characteristics for the present example in contrast to the comparative example. The present example illustrated in FIG. 6 is a gallium nitride based semiconductor laser device having a p-type Al_{0.025}Ga_{0.975}N cladding layer 32 and an n-type Al_{0.04}Ga_{0.96}N cladding layer 22, where the thickness H of the ridge portion 42 is 0.35 μm. The comparative example illustrated in FIG. 6 is a gallium nitride based semiconductor laser device having a p-type Al_{0.025}Ga_{0.975}N cladding layer 32 and an n-type Al_{0.025}Ga_{0.975}N cladding layer 22, where the thickness H of the ridge portion 42 is 0.5 μm.

The casing temperature Tc is −10, 25, and 80° C. in both cases. Note that the casing temperature is used as a parameter Instead of the ambient temperature so as not to include the heat sink dependence. In the present example, indicated by solid lines, the operating current at CW 100 mW is about 130 mA (Tc=−10° C.), about 150 mA (Tc=25° C.), and about 175 mA (Tc=80° C.). On the other hand, in the comparative example, the operating current is increased to about 200 mA (Tc=−10° C.), about 220 mA (Tc=25° C.), and about 270 mA (Tc=80° C.), respectively. Moreover, in the comparative example, the power tends to be saturated. Thus, in the comparative example, the long-term reliability is decreased because of difficulty in achieving high power and the increased operating temperature due to the decreased efficiency.

Rewritable applications for next-generation DVDs require a CW power of 100 mW or more and a pulse power of 200 mW or more. The present example can be operated at a CW power of 100 mW or more and at a low current of 200 mA or less over the range of −10 to 80° C. without generating kinks by appropriately selecting the thickness of the ridge portion 42, the aluminum composition ratio of the p-type AlGaN cladding layer 32, and the structure of the p⁺-type overflow prevention layer 28.

Next, a variation of the present example is presented. To begin with, a description is given of the problems occurring when the insulating film 36 is thicker than the thickness of the ridge portion 42.

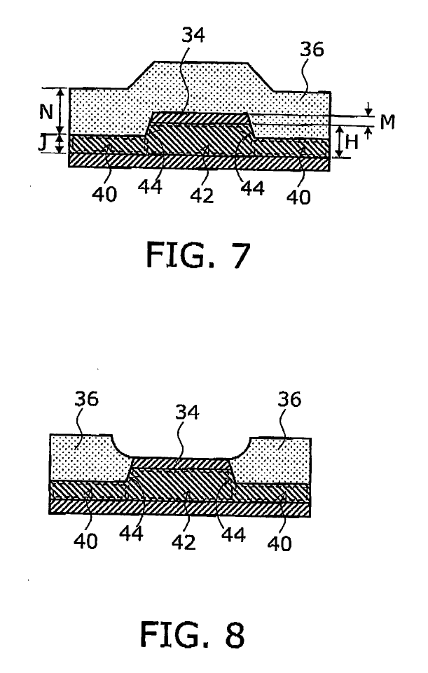

FIGS. 7 to 9 are process cross sections showing the relevant part of a process of manufacturing such a gallium nitride based semiconductor laser device.

FIG. 7 shows a cross section where the sum of the thickness H of the ridge portion 42 and the thickness M of the p⁺-type GaN contact layer 34 is less than the sum of the thickness 3 of the non-ridge portion 40 and the thickness N of the insulating film 36.

A patterned mask material (not shown) is provided on the insulating film 36, which is then patterned as illustrated in FIG. 8. Here, the Insulating film 36 tends to be overetched for the purpose of completely exposing the surface of the p⁺-type GaN contact layer 34. Subsequently, the p-side electrode 50 is formed as shown in FIG. 9. Here, the insulating film 36 may be removed at part of the ridge side face 44 of the ridge portion 42. This may result in insufficiency of the horizontal optical confinement.

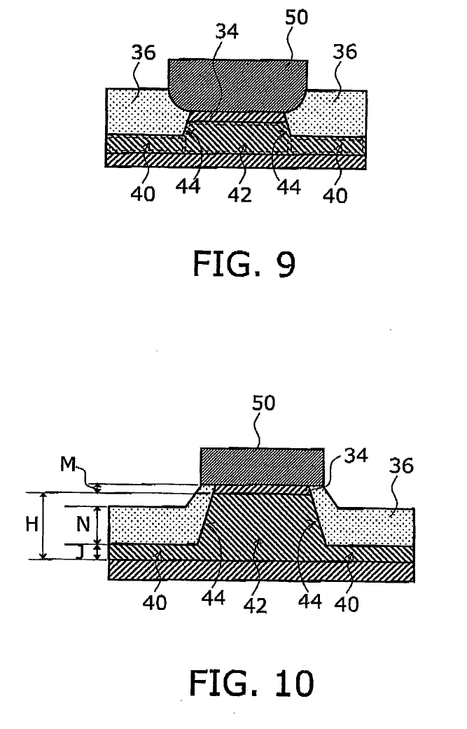

FIG. 10 is a partial schematic cross section showing the relevant part of a gallium nitride based semiconductor laser device according to a variation of the example, which solves the above problems. More specifically, the exposure of the ridge side face 44 of the ridge portion 42 can be prevented when the sum of the thickness H of the ridge portion 42 and the thickness M of the p⁺-type GaN contact layer 34 is not less than the sum of the thickness 3 of the non-ridge portion 40 and the thickness N of the insulating film 36. Moreover, if the surface of the insulating film 36 is made substantially coplanar with the surface of the p⁺-type contact layer 34, the p-side electrode 50 can be widened to improve heat dissipation to the heat sink. The thickness of the Insulating film 36 can be selected within the range of 0.1 to 0.4 μm, for example.

The above examples are described in the cases where the n-type GaN substrate 20 is used. However, the invention is not limited thereto. For example, semiconductor laminated films can be formed by ELOG (Epitaxial Lateral OverGrowth) on a sapphire substrate. The advantage of using the n-type GaN substrate 20 is summarized as follows. In contrast to sapphire, the n-type GaN substrate 20 can provide an extremely good crystallinity in the crystal growth of semiconductor laminated films because it is lattice matched. Moreover, the need for forming buffer layers and for heat treatment is eliminated, and thus the manufacturing process can be simplified.

Furthermore, the n-side electrode 52 can be formed on the rear side of the n-type GaN substrate 20. Thus the electrodes can be placed on both sides as in semiconductor laser devices based on such materials as InGaAlP, GaAs, and InP. This results in simplifying the assembling process, thereby improving the reliability.

Moreover, the current path to the n-side electrode 52 is vertical with respect to the chip. In the case of ELOG on a sapphire substrate, the current path is horizontal with respect to the semiconductor lamination, which may increase the resistive component and raise the operating voltage. In contrast, when the n-type GaN substrate 20 is used, the resistive component on the substrate side can be reduced.

Embodiments of the invention have been described with reference to examples. However, the invention is not limited thereto. Any size, material, and arrangement of various elements constituting the semiconductor laser device with its ridge portion being a waveguide that are variously adapted by those skilled in the art are also encompassed within the scope of the invention as long as they include the features of the invention.

1. A gallium nitride based semiconductor laser device comprising:
a first cladding layer having a first conductivity type;
an active layer provided on the first cladding layer;
an overflow prevention layer having a second conductivity type provided on the active layer; and
a second cladding layer having the second conductivity type provided on the overflow prevention layer,
the active layer having a multiple quantum well structure including a plurality of well layers made of gallium nitride based semiconductor and a plurality of barrier layers made of gallium nitride based semiconductor, number of the well layers being 2 to 4, thicknesses of the well layers being 2 to 5 nanometers, and thicknesses of the barrier layers being 3 to 10 nanometers,
the second cladding layer having a ridge portion and a non-ridge portion, and made of an AlₓGa₁₋ₓN (0.015≦x≦0.040), and
a thickness of the ridge portion being not less than a thickness of the non-ridge portion, not less than 0.1 micrometers and not more than 0.45 micrometers.

2. A gallium nitride based semiconductor laser device according to claim 1, wherein the overflow prevention layer is made of Al_{z}Ga_{1-z}N where the aluminum composition ratio z is 0.15 or more.

3. A gallium nitride based semiconductor laser device according to claim 1, wherein the first cladding layer has a superlattice layer including Al_{y}Ga_{1-y}N (0.04≦y≦1) layers and GaN layers with an average aluminum composition ratio of 0.04 or more and 0.10 or less.

4. A gallium nitride based semiconductor laser device according to claim 1, wherein the first cladding layer is made of an AlₓGa₁₋ₓN (0.04≦x≦0.10).

5. A gallium nitride based semiconductor laser device according to claim 1, wherein the active layer has a single or multiple quantum well structure of InₓGa₁₋ₓN/In_{y}Ga_{1-y}N, where the indium composition ratio x of the well layer is 0.05 or more and 0.2 or less, and the indium composition ratio y of the barrier layer is 0 or more and 0.05 or less.

6. A gallium nitride based semiconductor laser device according to claim 1, further comprising:
a contact layer having the second conductivity type provided on an upper face of the ridge portion; and
an insulating film provided on a side face of the ridge portion and an upper face of the non-ridge portion.

7. A gallium nitride based semiconductor laser device according to claim 6,
wherein a fundamental horizontal transverse mode of emitted light from the active layer is confined due to a refractive index difference between the second cladding layer constituting the ridge portion and the insulating film, and
a sum of the thickness of the ridge portion and the thickness of the contact layer is not less than the sum of the thickness of the non-ridge portion and the thickness of the insulating film.

8. A gallium nitride based semiconductor laser device according to claim 6, wherein a thickness of the insulating film is not less than 0.1 micrometers and not more than 0.4 micrometers.

9. A gallium nitride based semiconductor laser device according to claim 1, wherein an average aluminum composition ratio of the second cladding layer is not less than 0.015 and not more than 0.035.

10. A gallium nitride based semiconductor laser device according to claim 1, wherein the thickness of the ridge portion is greater than the thickness of the non-ridge portion by 0.05 micrometers or more.

11. A gallium nitride based semiconductor laser device comprising:
a first cladding layer having a first conductivity type;
an active layer provided on the first cladding layer;
an overflow prevention layer having a second conductivity type provided on the active layer; and
a second cladding layer having the second conductivity type provided on the overflow prevention layer,
the active layer having a multiple quantum well structure including a plurality of well layers made of gallium nitride based semiconductor and a plurality of barrier layers made of gallium nitride based semiconductor, number of the well layers being 2 to 4, thicknesses of the well layers being 2 to 5 nanometers, and thicknesses of the barrier layers being 3 to 10 nanometers.
the second cladding layer having a ridge portion and a non-ridge portion, and a superlattice layer of Al_{y}Ga_{1-y}N (0.015≦y≦1) and GaN with an average aluminum composition ratio of 0.015 or more and 0.040 or less, and
the thickness of the ridge portion being not less than the thickness of the non-ridge portion, not less than 0.1 micrometers and not more than 0.45 micrometers.

12. A gallium nitride based semiconductor laser device according to claim 11, wherein the overflow prevention layer is made of Al_{z}Ga_{1-z}N where the aluminum composition ratio z is 0.15 or more.

13. A gallium nitride based semiconductor laser device according to claim 11, wherein the first cladding layer has a superlattice layer including Al_{y}Ga_{1-y}N (0.04≦y≦1) layers and GaN layers with an average aluminum composition ratio of 0.04 or more and 0.10 or less.

14. A gallium nitride based semiconductor laser device according to claim 11, wherein the first cladding layer is made of AlₓGa₁₋ₓN (0.04≦x≦0.10).

15. A gallium nitride based semiconductor laser device according to claim 11, wherein the active layer has a multiple quantum well structure of InₓGa₁₋ₓN/In_{y}Ga_{1-y}N, where the indium composition ratio x of the well layer is 0.05 or more and 0.2 or less, and the indium composition ratio y of the barrier layer is 0 or more and 0.05 or less.

16. A gallium nitride based semiconductor laser device according to claim 11, further comprising:
a contact layer having the second conductivity type provided on an upper face of the ridge portion; and
an insulating film provided on a side face of the ridge portion and an upper face of the non-ridge portion.

17. A gallium nitride based semiconductor laser device according to claim 16,
wherein a fundamental horizontal transverse mode of emitted light from the active layer is confined due to a refractive index difference between the second cladding layer constituting the ridge portion and the insulating film, and
a sum of the thickness of the ridge portion and the thickness of the contact layer is not less than the sum of the thickness of the non-ridge portion and the thickness of the insulating film.

18. A gallium nitride based semiconductor laser device according to claim 16, wherein a thickness of the insulating film is not less than 0.1 micrometers and not more than 0.4 micrometers.

19. A gallium nitride based semiconductor laser device according to claim 11, wherein an average aluminum composition ratio of the second cladding layer is not less than 0.015 and not more than 0.035.

20. A gallium nitride based semiconductor laser device according to claim 11, wherein the thickness of the ridge portion is greater than the thickness of the non-ridge portion by 0.05 micrometers or more.
